(19) United States
(12) Patent Application Publication
(10) Pub. No.: US 2008/0101628 A1
(43) Pub. Date: May 1, 2008

(54) Switching amplifier circuits and methods

(75) Inventor: Hideto Takagishi, San Jose, CA (US)

Correspondence Address: FOUNTAINHEAD LAW GROUP, PC, 900 LAFAYETTE STREET, SUITE 509, SANTA CLARA, CA, 95050, US

(73) Assignee: PacificTech Microelectronics, Inc., Grand Cayman (KY)

(21) Appl. No.: 11/588,799

(22) Filed: Oct. 27, 2006

(51) Int. Cl. H03F 21/00; H02B 1/00; H03F 3/38

(52) U.S. Cl. 381/120; 330/10; 330/251; 381/123

(57) ABSTRACT

Embodiments of the present invention include switching amplifier circuits and methods. In one embodiment, the present invention includes an audio amplification method comprising modulating an audio input signal to produce a first modulated signal and a second modulated signal, amplifying the first modulated signal to generate an amplified first modulated signal at a first output terminal of an amplifier, and amplifying the second modulated signal to generate an amplified second modulated signal at a second output terminal of the amplifier, wherein the first output terminal of the amplifier is constant when the second output terminal of the amplifier is switching, and wherein the second output terminal of the amplifier is constant when the first output terminal of the amplifier is switching.

### BACKGROUND

The present invention relates to amplifiers, and in particular, switching amplifier circuits and methods.

A switching amplifier, sometimes referred to as a class D amplifier, is an amplifier where the output transistors are operated as switches. One example of a transistor used in switching amplifiers is a MOSFET. When the transistor is off, the circuit behaves like an open circuit so the current is zero. When the transistor is on, the voltage across the transistor is ideally zero. In practice, the voltage is very small. Since the equation for power is P=V*I, the power dissipated by the amplifier is very low in both states. This increases the efficiency, thus requiring less power from the power supply and allowing smaller heat sinks for the amplifier. For example, the increased efficiency translates into benefits such as longer battery life. The decrease in the size of the heat sinks lowers the weight, cost and size of the amplifier. Example applications where these advantages would be useful are portable battery-powered equipment such as cellular technology or portable music players.

FIG. 1 illustrates a block diagram of a switching amplifier 100. A continuous input signal is received by a modulator 101 and converted into a train of pulses. The input signal is transformed into a stream of pulses where the pulse characteristics are linked to the amplitude of the input signal. For example, within each period, the duty cycle of a pulse may be proportional to the amplitude of the input signal. For instance, if the input signal received is constant at zero, the duty cycle of the output pulses may be 50%. If the input signal received is highly positive, the duty cycle of the output pulses may be near 100%. Conversely, if the input signal received is highly negative, the duty cycle may be near 0%.

The modulated signal is then amplified in a switching output stage 102. Since the modulated signal is represented by a train of pulses, the output transistors operate like switches. This enables the transistors to have zero current when they are not switching and a low voltage drop across the transistors when they are switching.

The amplified signal generated by output stage 102 then enters a low pass filter 103 before entering a speaker 104. The low pass filter translates the modified amplified signal back into a continuous signal. A typical filter is an LC filter, for example. The resulting amplified continuous signal may be provided to a speaker and translated into sound. The benefits of low pass filters include minimizing electromagnetic interference (“EMI”) and power dissipation in the amplified signal.

However, one disadvantage of switching amplifiers is the cost and size of the LC filter. The components, especially the inductors, occupy board space and add to the overall cost. To address this, a separate inductor is sometimes eliminated to create what is referred to as an inductorless amplifier. FIG. 2 illustrates a fully differential inductorless circuit. The pulse width modulated signal is amplified by amplifier 201. Similarly, the inverse of the pulse width modulated signal is amplified by amplifier 202. The amplifiers are coupled to speaker 203. The signals transmitted to the speaker are typically voltages and currents. Speakers typically include a wire coil. In this application, the wire coil is used as the inductance for filtering the amplified signals. Accordingly, a separate low pass filter inductor is not needed. However, one disadvantage of removing the low pass filter is higher EMI levels. EMI is caused by high power switching signals 210 and 211, which may be transmitted at the output of an integrated circuit, across a printed circuit board, and through wires to a speaker. Additionally, existing differential solutions require two power amplifiers for driving both terminals of the speaker. Each power amplifier may be driving high currents across potentially large voltage swings, resulting in high power dissipation across a potentially wide range of frequencies.

Thus, there is a need for an improved switching amplifier capable of low EMI and power dissipation in inductorless applications. The present invention solves these and other problems by providing improved switching amplifier circuits and methods.

### SUMMARY

Embodiments of the present invention include switching amplifier circuits and methods. In one embodiment, the present invention includes an audio amplification method comprising modulating an audio input signal to produce a first modulated signal and a second modulated signal, amplifying the first modulated signal to generate an amplified first modulated signal at a first output terminal of an amplifier, and amplifying the second modulated signal to generate an amplified second modulated signal at a second output terminal of the amplifier, wherein the first output terminal of the amplifier is constant when the second output terminal of the amplifier is switching, and wherein the second output terminal of the amplifier is constant when the first output terminal of the amplifier is switching.

In one embodiment, modulating comprises half-wave rectifying the audio signal and an inverse of the audio signal to produce first and second half-wave rectified signals, and pulse width modulating the first and second half-wave rectified signals to produce the first and second modulated signals.

In one embodiment, modulating comprises pulse width modulating the audio signal and an inverse of the audio signal to produce first and second pulse width modulated signals, and digitally half-wave rectifying the first and second pulse width modulated signals to produce the first and second modulated signals.

In one embodiment, the present invention further comprises coupling the amplified first modulated signal to a first integrated circuit package terminal and coupling the amplified second modulated signal to a second integrated circuit package terminal.

In one embodiment, the present invention further comprises coupling the first integrated circuit package terminal to a first terminal of a speaker and coupling the second integrated circuit package terminal to a second terminal of a speaker.

In one embodiment, the audio input signal is a single ended signal, the method further comprising generating an inverse of the audio input signal.

In one embodiment, the audio input signal is a differential signal.

In one embodiment, first and second modulated signals are pulse width modulated signals.

In one embodiment, the present invention includes an electronic circuit comprising a modulator having at least one input for receiving an input signal, the modulator generating a first modulated signal on a first modulator output terminal and a second modulated signal on a second modulator output terminal, and an amplifier having a first input coupled to receive the first modulated signal and a second input coupled to receive the second modulated signal, the amplifier generating a first amplified modulated signal on a first output terminal and the amplifier generating a second amplified modulated signal on a second output terminal, wherein the first output terminal of the amplifier is constant when the second output terminal of the amplifier is switching, and wherein the second output terminal of the amplifier is constant when the first output terminal of the amplifier is switching.

In one embodiment, the modulator comprises a first comparator coupled to receive the input signal, a second comparator coupled to receive an inverse of the input signal, a sawtooth wave generator coupled to the first and second comparators, and a digital half-wave rectifying circuit having a first input coupled to an output of the first comparator and a second input coupled to an output of the second comparator.

In one embodiment, the digital half-wave rectifying circuit comprises an XNOR circuit having a first input coupled to the output of the first comparator and a second input coupled to the output of the second comparator, a first NOR circuit having a first input coupled to the output of the first comparator and a second input coupled to the output of the XNOR circuit, and a second NOR circuit having a first input coupled to the output of the second comparator and a second input coupled to the output of the XNOR circuit.

In one embodiment, the modulator comprises first means for comparing the received the input signal to a sawtooth waveform, second means for comparing the received an inverse of the input signal to a sawtooth waveform, and means for digitally half-wave rectifying coupled to the first and second means for comparing.

In one embodiment, the modulator comprises a first half-wave rectifier coupled to receive the input signal, a second half-wave rectifier coupled to receive an inverse of the input signal, a first comparator coupled to the output of the first half-wave rectifier, a second comparator coupled to the output of the second half-wave rectifier, and a sawtooth wave generator coupled to the first and second comparators.

In one embodiment, the modulator comprises first means for half-wave rectifying coupled to receive the input signal, second means for half-wave rectifying coupled to an inverse of the input signals, first means for comparing the half-wave rectified input signal to a sawtooth waveform, and second means for comparing the half-wave rectified inverse of the input signal to a sawtooth waveform.

In one embodiment, the first output terminal is coupled to a first integrated circuit package terminal and the second output terminal is coupled to a second integrated circuit package terminal.

In one embodiment, the present invention includes an audio amplifier comprising means for modulating an audio signal to produce a first modulated signal and a second modulated signal, means for amplifying the first modulated signal to generate a first amplified modulated signal and a second amplified modulated signal, wherein the first amplified modulated signal is constant when the second amplified modulated signal is switching, and wherein the second amplified modulated signal is constant when the first amplified modulated signal is switching.

In one embodiment, modulating comprises means for half-wave rectifying the audio signal and an inverse of the audio signal to produce the first and second half-wave rectified signals, and means for pulse width modulating the first and second half-wave rectified signals to produce the first and second modulated signals.

In one embodiment, modulating comprises means for pulse width modulating the audio signal and an inverse of the audio signal to produce first and second pulse width modulated signals, and means for digitally half-wave rectifying the pulse width modulated signals to produce the first and second modulated signals.

In one embodiment, the present invention includes an electronic circuit comprising a modulator having at least one input for receiving an input signal, the modulator generating a first modulated signal on a first modulator output terminal and a second modulated signal on a second modulator output terminal, and an amplifier having a first input coupled to receive the first modulated signal and a second input coupled to receive the second modulated signal, the amplifier generating a first amplified modulated signal on a first output terminal during a first time period and the amplifier generating a second amplified modulated signal on a second output terminal during a second time period, wherein the first amplified modulated signal is constant during the first time period when the second amplified modulated signal is switching, and wherein the second amplified modulated signal is constant during the second time period when the first amplified modulated signal is switching.

In one embodiment, the present invention further comprises an inverter circuit for generating an inverse of the first input signal.

In one embodiment, the modulator comprises a sawtooth wave generator.

In one embodiment, the modulator comprises a plurality of comparators.

In one embodiment, the modulator comprises a digital half-wave rectifier. In one embodiment, the digital half-wave rectifier comprises a XNOR gate, a first NOR gate and a second NOR gate.

In one embodiment, the modulator comprises a first half-wave rectifier coupled to receive the input signal and a second half-wave rectifier coupled to receive an inverse of the input signal.

In one embodiment, the amplifier comprises a first transistor having a first terminal coupled to a first reference voltage, a second terminal coupled to the first output terminal, and a control terminal coupled to the first amplifier input, a second transistor having a first terminal coupled to a second reference voltage, a second terminal coupled to the first output terminal, and a control terminal coupled to the first amplifier input, a third transistor having a first terminal coupled to the first reference voltage, a second terminal coupled to the second output terminal, and a control terminal coupled to the second amplifier input, and a fourth transistor having a first terminal coupled to the second reference voltage, a second terminal coupled to the second output terminal, and a control terminal coupled to the second amplifier input.

In one embodiment, the present invention includes a method of driving a speaker comprising generating a first pulse width modulated half-wave rectified signal on a first output terminal of a first amplifier, and generating a second pulse width modulated half-wave rectified signal on a second output terminal of a second amplifier; wherein the first signal is constant when the second signal is switching, and wherein the second signal is constant when the first signal is switching.

In one embodiment, the present invention further comprises modulating an audio input signal to produce a first modulated signal and a second modulated signal.

In one embodiment, the present invention further comprises amplifying the first modulated signal and amplifying the second modulated signal.

Additional embodiments will be evident from the following detailed description and accompanying drawings, which provide a better understanding of the nature and advantages of the present invention.

### BRIEF DESCRIPTION OF THE DRAWINGS

FIG. 1 illustrates a typical switching amplifier.

FIG. 2 illustrates a inductorless switching amplifier.

FIG. 3 illustrates a switching amplifier according to one embodiment of the present invention.

FIG. 4 is an example of a switching amplifier according to one embodiment of the present invention.

FIG. 5 illustrates waveforms in the switching amplifier of FIG. 4.

FIG. 6 illustrates digital modulation logic according to one embodiment of the present invention.

FIG. 7 is an example of a switching amplifier according to one embodiment of the present invention.

FIG. 8 illustrates waveforms in the switching amplifier of FIG. 7.

FIG. 9 illustrates amplifiers according to one embodiment of the present invention.

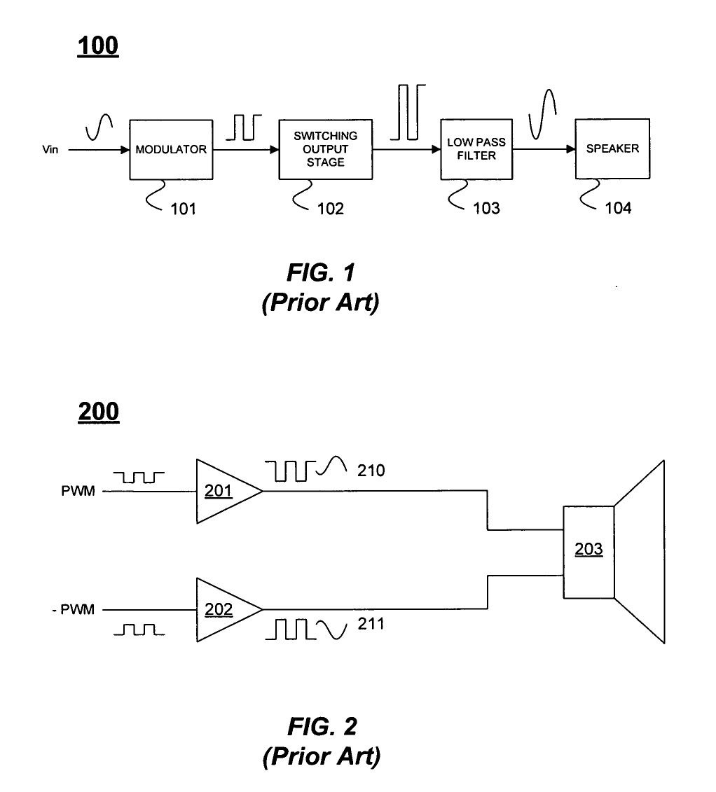

### DETAILED DESCRIPTION

Described herein are techniques for switching amplifiers. In the following description, for purposes of explanation, numerous examples and specific details are set forth in order to provide a thorough understanding of the present invention. It will be evident, however, to one skilled in the art that the present invention as defined by the claims may include some or all of the features in these examples alone or in combination with other features described below, and may further include obvious modifications and equivalents of the features and concepts described herein.

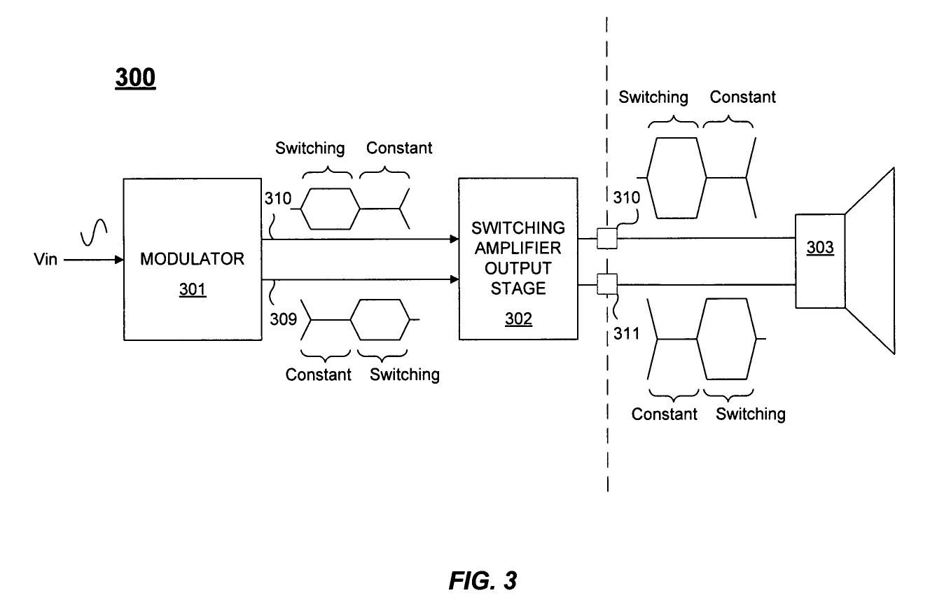

FIG. 3 illustrates a switching amplifier according to one embodiment of the present invention. Switching amplifier 300 is an electronic circuit that may be implemented using either discrete devices or as a fully integrated circuit on a single silicon die, for example. Circuit 300 includes a modulator 301 having one or more inputs for receiving an audio input signal (Vin). In one embodiment, modulator 301 receives a single ended signal. In other embodiments, modulator 301 may receive a differential audio signal. Modulator 301 translates the continuous time analog audio signal into a modulated signal. An example modulation schemes include pulse width modulation. However, other modulation techniques could be used. Modulator 301 includes two output terminals that carry first and second modulated signals. As illustrated in FIG. 3, the output of the modulator may operate differently during depending on the state of the input signals. For example, if the input signals increases, the modulation signal at terminal 308 may be held constant while the other modulation signal at terminal 309 switches (e.g., generates pulses or transitions between two voltages). Alternatively, if the input signal decreases, the modulation signal at terminal 309 may be held constant while the other modulation signal at terminal 308 switches. Accordingly, one embodiment of the present invention includes a modulation scheme wherein a first modulated signal is constant when a second modulated signal is switching, and the second modulated signal is constant when the first modulated signal is switching.

The modulator output terminals 308 and 309 are coupled to the input terminals of a switching amplifier output stage 302. Amplifier 302 may receive the modulated signals and amplify the signals (e.g., the current) to drive a speaker, for example. Amplifier 302 may include output terminals for provided amplified modulated signals corresponding to the modulated signals received from modulator 301. If the circuits are implemented on an integrated circuit, the amplified modulated signals may be coupled from output terminals of the amplifier to integrated circuit package terminals 310 and 311 for example. The dashed line represents the boundary between an integrated circuit and a printed circuit board, for example. The package terminals may, in turn, be coupled to a speaker. Therefore, if an audio input signals increases (e.g., above zero for an audio signal with no DC offset or above half-supply for an audio signal that is operating around half-supply), one terminal of the speaker (e.g., coupled to terminal 310) may be held constant while the other terminal of the speaker (e.g., coupled to terminal 311) receives the amplified modulated signal. Similarly, if the audio input signal decrease, the other terminal of the speaker (e.g., coupled to terminal 311) may be held constant while the opposite terminal of the speaker (e.g., coupled to terminal 310) receives the modulated signal. Based on the modulation techniques describe above, it can be seen that the first output terminal of the amplifier is constant (e.g., zero volts) when the second output terminal of the amplifier is switching, and the second output terminal of the amplifier is constant (e.g., zero volts) when the first output terminal of the amplifier is switching. When no input signal is received a very short pulse may appear on both positive and negative outputs (i.e. current through load is negligible), for example.

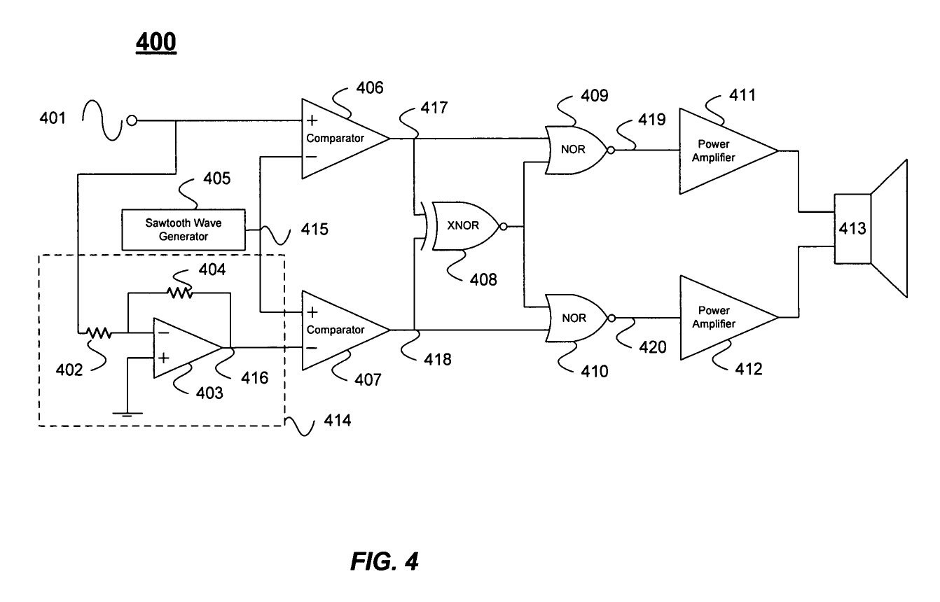

FIG. 4 illustrates a switching amplifier according to one embodiment of the present invention. The switching amplifier 400 includes inverter circuit 414, sawtooth wave generator 405, comparators 406 and 407, XOR gate 408, NOR gates 409 and 410, power amplifiers 411 and 412, and speaker 413. In this example, inverter circuit 414 includes amplifier 403 and two resisters 402 and 404. The positive input of amplifier 403 is grounded. Resistor 402 is coupled between the negative input of amplifier 403 and the input of inverter 414. Resistor 404 is coupled between the negative input and output of amplifier 403.

An input analog signal 401 is received by circuit 400 and is transmitted to comparator 406 and inverter circuit 414. In this example, the input signal 401 is a single ended signal, and inverter circuit 414 may be used to generate an inverse of the signal. Other embodiments of the invention, the input signal may be a fully differential signal, in which case an inverter circuit may be not be used. In this example, the means for modulating the inputs signal include two comparators 406 and 407, sawtooth wave generator 405, and a digital circuit for generating the desired output signals—here XNOR 408, NOR 409 and 410 are digitally half-wave rectifying the pulse width modulated signals (e.g., using digital subtraction) to create a modulated representation of a half cycle of the audio signal. A modulated representation of a half cycle of the input audio signal, positive or negative, is referred to herein as a half-wave rectified modulated signal, or in the case of PWM a half-wave rectified pulse width modulated signal.

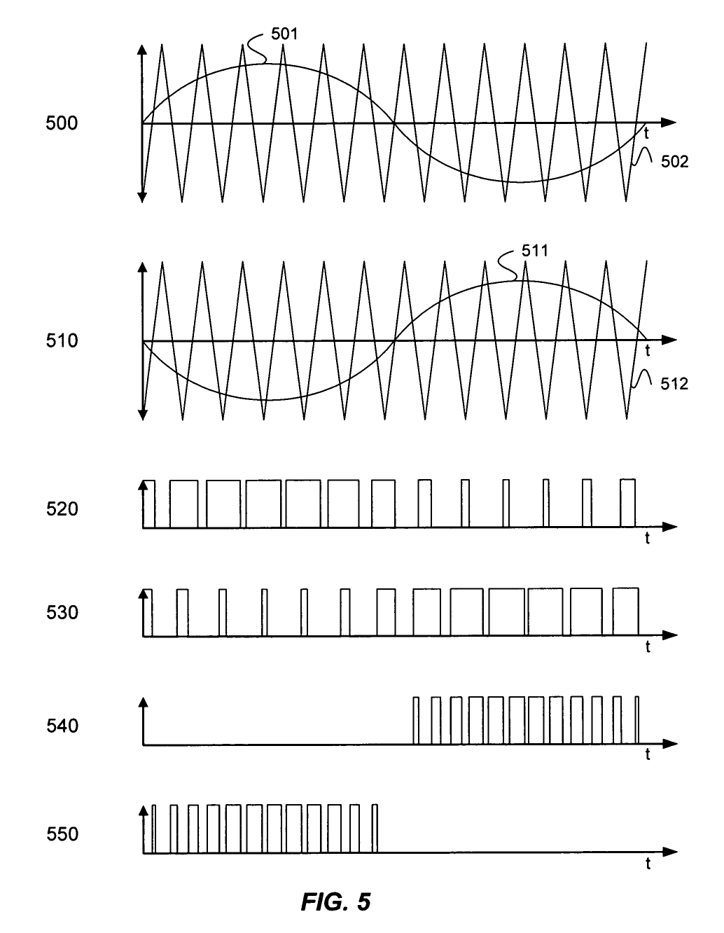

Comparator 406 receives the input signal on the positive input terminal and a sawtooth waveform on the negative input terminal at node 415 and generates a pulse width modulated signal at node 417. Plot 500 in FIG. 5 illustrates one example of the waveforms received by comparator 406. The comparator functions by outputting a high value whenever the input signal is positive in comparison with sawtooth waveform and outputting a low value whenever the input waveform is more negative in comparison with the sawtooth waveform. The sawtooth waveform 502 may have a larger amplitude than analog signal 501 so that the duty cycle of the modulated signal will not be 0% or 100%. When the duty cycle of the modulated signal is either 0% or 100%, known as full modulation, it is difficult to distinguish between two different input signal amplitudes because the amplitudes of the input signals are larger than the amplitude of the sawtooth waveform. The modulated signal at the output of comparator 406 is illustrated on 520 in FIG. 5. Pulse width modulated signals lead to very little loss across the transistors, which is one principle behind class D modulation that allows them to attain such high efficiency. In one embodiment, the sawtooth waveform generated by the sawtooth wave generator modulates at a frequency of approximately 100 times the input signal frequency so that a more accurate representation of the analog signal may be obtained.

Similarly, comparator 407 receives inverse input analog signal on the positive input terminal at node 416 and sawtooth waveform on the negative input terminal at node 415. Plot 510 in FIG. 5 illustrates one example of the incoming signals where 511 is the inverted (or differential) input signal and 512 is the sawtooth waveform. The pulse width modulated signal at node 418 generated by comparator 507 is illustrated in 530 in FIG. 5. In another embodiment of the present invention, inverter circuit 514 may be moved between sawtooth wave generator 405 and comparator 407 so that the output for 407 is generated by receiving the inverted sawtooth waveform and the non-inverted input signal.

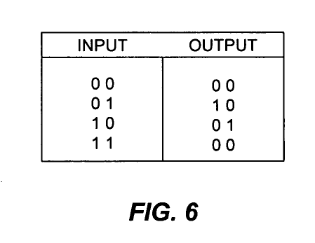

The combinational logic consisting of XNOR gate 408, NOR gate 409, and NOR gate 410 processes the signal at nodes 417 and 418 into half-wave rectified, pulse width modulated representations of the inverted and non-inverted input analog signal. The signal at node 419 represents the half-wave rectified, pulse width modulated representation of the inverted input analog signal, while the signal at node 420 represents the half-wave rectified pulse width modulated representation of the input analog signal. Plot 540 in FIG. 5 illustrates the signal at node 419. As can be seen from the figure, the signal at node 419 represents the subtraction of the signal at node 418 from the signal at node 417 where negative values resulting from the subtraction take on the value of zero. The truth table of the combinational logic is illustrated in FIG. 6. Similarly, 550 in FIG. 5 illustrates the signal at node 420. As can be seen from the figure, the signal is represented by the subtraction of the signal at nodes 417 and 418 where negative values resulting from the subtraction take on the value of zero. The signals at nodes 419 and 420 are amplified by power amplifiers 411 and 412, respectively, and then sent to speaker 413. Accordingly, the output terminal of amplifier 411 is constant when the output terminal of amplifier 411 is switching, and the output terminal of amplifier 412 is constant when the output terminal of amplifier 411 is switching.

One advantage to using the switching amplifier architecture shown in FIG. 4 is that it allows higher efficiency than traditional architectures. Traditionally, the signals generated by the power amplifiers in an inductorless switching circuit are fully differential meaning that both signals entering the speaker are switching. Loss occurs in the power amplifier whenever the incoming signal switches value. This is commonly known as “switching loss.” In circuit 400, power amplifiers 411 and 412 will experience less power loss because signals 419 and 420 are not always switching. By holding one signal constant while the other signal switches, there will be less loss occurring in the power amplifiers, which results in higher overall amplifier efficiency.

Another advantage to using the switching amplifier architecture shown in FIG. 4 is that it creates less EMI than traditional architectures. EMI is emitted as a by-product of electrical circuits carrying rapidly changing signals. This by-product creates unwanted signals which may cause interference and noise in nearby circuits, thereby degrading and limiting the effective performance of these circuits. Traditionally, the signals generated by the power amplifiers are fully differential meaning that both signals entering the speaker are switching. In circuit 400, the signal at node 419 is held constant while the signal at node 420 switches and vice versa. Accordingly, the output terminal of the first amplifier 411 is constant when the output terminal of the second amplifier 412 is switching, and the output terminal of the second amplifier 412 is constant when the output terminal of the first amplifier 411 is switching. This leads results in less switching noise, and therefore, less EMI, because only one power amplifier is creating switching noise on its output terminal.

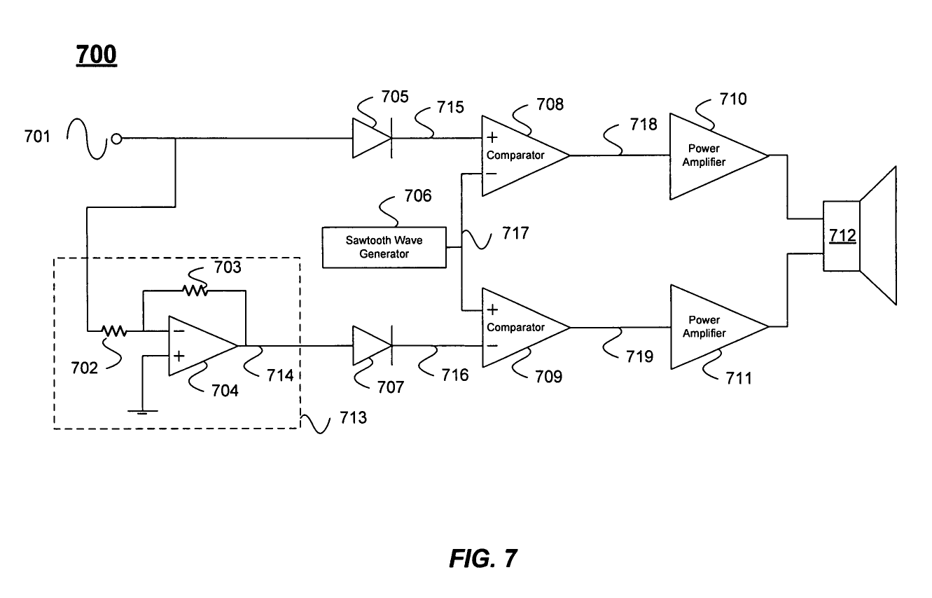

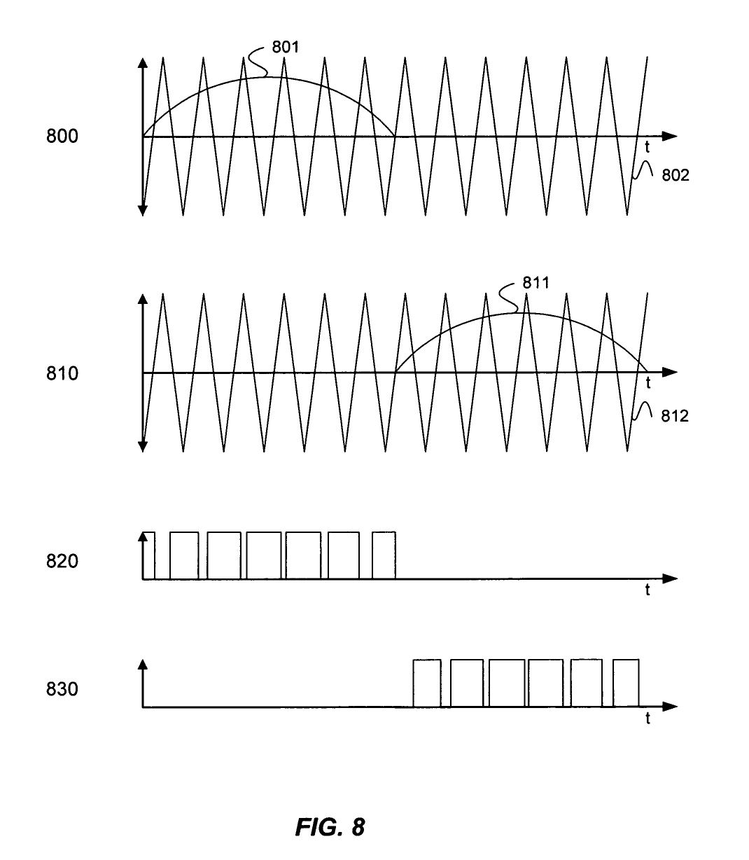

FIG. 7 illustrates a switching amplifier according to another embodiment of the present invention. The switching amplifier 700 includes inverter circuit 713, sawtooth wave generator 706, half-wave rectifiers 705 and 707, comparators 708 and 709, power amplifiers 710 and 711, and speaker 712. In this example, inverter circuit 713 includes amplifier 704 and resistors 702 and 703. The positive input of amplifier 704 is coupled to ground. Resistor 702 is coupled between the negative input of amplifier 704 and the incoming signal 701. Resistor 703 is coupled between the negative input and output of amplifier 704. In this example, the means for modulating include half wave rectifiers 705 and 706 (e.g., diodes), comparators 708 and 709, and sawtooth waveform generator 706.

Input analog signal 701 is received by circuit 700 and transmitted to half-wave rectifier 705 and inverter circuit 713. The half-wave rectifier transmits only the positive portions of the incoming signal to the output. Comparator 708 receives the half-wave rectified signal at node 715 along with the sawtooth waveform at node 717, which is generated by sawtooth wave generator 706. Plot 800 in FIG. 8 illustrates one example of the waveforms received by comparator 708. Sawtooth waveform 802 may have a larger amplitude than half-wave rectified signal 801 so that the maximum and minimum values of the input signal may be preserved in the pulse with modulated signal. The resulting pulse width modulated signal at node 718 is illustrated in plot 820 in FIG. 8. The signal at node 718 represents the pulse width modulated representation of the positive cycle of the input signal. The negative portions of the incoming signal are held constant for the purpose of achieving an affect similar to the circuit illustrated in FIG. 4. In one embodiment, the sawtooth waveform generated by sawtooth wave generator 706 modulates at a frequency of approximately 100 times the input signal frequency, allowing a more accurate pulse width modulated model of the analog signal to be generated. Similarly, half-wave rectifier 707 receives the inverted input signal at node 714 and sends the output to comparator 709. Comparator 709 then compares the half-wave rectified signal at node 716 with the sawtooth waveform at node 717 to generate the pulse width modulated signal at node 719. Plot 810 in FIG. 8 illustrates the half-wave rectified signal at node 716 as waveform 811 and the sawtooth waveform at node 717 as waveform 812. Plot 830 in FIG. 8 illustrates the output pulse width modulated signal at node 719. The signals at nodes 718 and 719 are amplified by power amplifiers 710 and 711, respectively, and then sent to speaker 713.

This embodiment contains the same advantages as shown in circuit 400 in FIG. 4. The decreased amount of switching in signals 718 and 719 equates to less switching loss and EMI when compared to traditional methods for the same reasons as stated above.

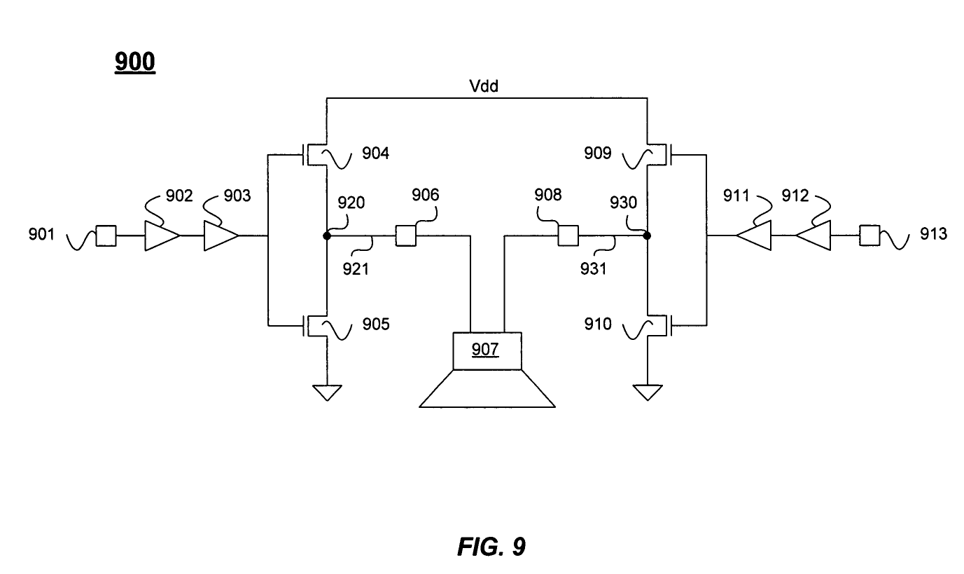

FIG. 9 illustrates an output amplifier according to one embodiment of the present invention. Amplifier 900 includes two input terminals 901 and 913. In this example the input terminals 901 and 913 of the amplifier are coupled to the output terminals 920 and 930, respectively, through a plurality of amplifier stages 902, 903, 912, and 911. Each amplifier stage may amplify the signal (e.g., the current) by a certain amount. The final output stage in this example includes four transistors. A first transistor 904 has a first terminal coupled to a first reference voltage such as a power supply voltage Vdd, a second terminal coupled to the first output terminal 920, and a control terminal coupled to the first amplifier input 901 through the stages 902 and 903. A second transistor 905 has a first terminal coupled to a second reference voltage such as ground, a second terminal coupled to the first output terminal 920, and a control terminal coupled to the first amplifier input 901. A third transistor has a first terminal coupled to the first reference voltage (e.g., Vdd), a second terminal coupled to the second output terminal 930, and a control terminal coupled to the second amplifier input 913 through stages 911 and 912. The fourth transistor has a first terminal coupled to the second reference voltage (e.g., ground), a second terminal coupled to the second output terminal 930, and a control terminal coupled to the second amplifier input 913. In an integrated circuit implementation, output terminals 920 and 930 may be coupled to metallization pads on the silicon die. The pads may be coupled to integrated circuit package terminals 906 and 907, for example, using bond wires, solder bumps (e.g., for chip scale packages) as illustrated at 921 and 931. The package terminal 920 may be coupled to a first terminal of a speaker, and package terminal 930 may be coupled to a second terminal of a speaker, for example. Accordingly, if the amplifier is driven with half-wave rectified pulse width modulated signals as described above, amplified modulated signals will be coupled to the integrated circuit package terminals 906 and 908, and in turn, to the terminals of speaker 907.

In one embodiment, another advantage of the present invention may include reductions in the size of the devices needed for the high side (between the output and supply) of the switching output because the average of the waveform is typically on the low side rather than the high side. For example, if the modulating output transitions between zero volts (0v) on the low side and another voltage, Vhi, on the high side, the average over 1 cycle of a sinewave input results in the high side output driver device (e.g., transistor 904 or 909) being on only about 25% of the time and the low side output driver device (e.g., transistor 905 or 910) being on about 75% of the time. Thus, smaller devices may be used on the high side. For example, if transistors 904 and 909 are P-channel devices, such devices may be decreased in size by about 30% using the techniques described above. If transistors 904 and 909 are N-channel devices, such devices may be decreased in size by about 15-20% using the techniques described above, for example.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. For example, switching amplifier circuits and methods according to the present invention may include some or all of the innovative features described above. Based on the above disclosure and the following claims, other arrangements, embodiments, implementations and equivalents will be evident to those skilled in the art and may be employed without departing from the spirit and scope of the invention as defined by the claims.

What is claimed is:

1. An audio amplification method comprising:
modulating an audio input signal to produce a first modulated signal and a second modulated signal;
amplifying the first modulated signal to generate an amplified first modulated signal at a first output terminal of an amplifier; and
amplifying the second modulated signal to generate an amplified second modulated signal at a second output terminal of the amplifier,
wherein the first output terminal of the amplifier is constant when the second output terminal of the amplifier is switching, and
wherein the second output terminal of the amplifier is constant when the first output terminal of the amplifier is switching.

2. The method of claim 1 wherein modulating comprises:
half-wave rectifying the audio signal and an inverse of the audio signal to produce first and second half-wave rectified signals; and
pulse width modulating the first and second half-wave rectified signals to produce the first and second modulated signals.

3. The method of claim 1 wherein modulating comprises:
pulse width modulating the audio signal and an inverse of the audio signal to produce first and second pulse width modulated signals; and
digitally half-wave rectifying the first and second pulse width modulated signals to produce the first and second modulated signals.

4. The method of claim 1 further comprising coupling the amplified first modulated signal to a first integrated circuit package terminal and coupling the amplified second modulated signal to a second integrated circuit package terminal.

5. The method of claim 4 further comprising coupling the first integrated circuit package terminal to a first terminal of a speaker and coupling the second integrated circuit package terminal to a second terminal of a speaker.

6. The method of claim 1 wherein the audio input signal is a single ended signal, the method further comprising generating an inverse of the audio input signal.

7. The method of claim 1 wherein the audio input signal is a differential signal.

8. The method of claim 1 wherein first and second modulated signals are pulse width modulated signals.

9. An electronic circuit comprising:
a modulator having at least one input for receiving an input signal, the modulator generating a first modulated signal on a first modulator output terminal and a second modulated signal on a second modulator output terminal; and
an amplifier having a first input coupled to receive the first modulated signal and a second input coupled to receive the second modulated signal, the amplifier generating a first amplified modulated signal on a first output terminal and the amplifier generating a second amplified modulated signal on a second output terminal,
wherein the first output terminal of the amplifier is constant when the second output terminal of the amplifier is switching, and
wherein the second output terminal of the amplifier is constant when the first output terminal of the amplifier is switching.

10. The circuit of claim 9 wherein the modulator comprises:
a first comparator coupled to receive the input signal;
a second comparator coupled to receive an inverse of the input signal;
a sawtooth wave generator coupled to the first and second comparators; and
a digital half-wave rectifying circuit having a first input coupled to an output of the first comparator and a second input coupled to an output of the second comparator.

11. The circuit of claim 10 wherein the digital half-wave rectifying circuit comprises:
an XNOR circuit having a first input coupled to the output of the first comparator and a second input coupled to the output of the second comparator;
a first NOR circuit having a first input coupled to the output of the first comparator and a second input coupled to the output of the XNOR circuit; and
a second NOR circuit having a first input coupled to the output of the second comparator and a second input coupled to the output of the XNOR circuit.

12. The circuit of claim 9 wherein the modulator comprises:
first means for comparing the received input signal to a sawtooth waveform;
second means for comparing an inverse of the received input signal to a sawtooth waveform; and
means for digitally half-wave rectifying coupled to the first and second means for comparing.

13. The circuit of claim 9 wherein the modulator comprises:
a first half-wave rectifier coupled to receive the input signal;
a second half-wave rectifier coupled to receive an inverse of the input signal;
a first comparator coupled to the output of the first half-wave rectifier;
a second comparator coupled to the output of the second half-wave rectifier; and
a sawtooth wave generator coupled to the first and second comparators.

14. The circuit of claim 9 wherein the modulator comprises:
first means for half-wave rectifying coupled to receive the input signal;
second means for half-wave rectifying coupled to an inverse of the input signal;
first means for comparing the half-wave rectified input signal to a sawtooth waveform; and
second means for comparing the half-wave rectified inverse of the input signal to the sawtooth waveform.

15. The circuit of claim 9 wherein the first output terminal is coupled to a first integrated circuit package terminal and the second output terminal is coupled to a second integrated circuit package terminal.

16. An audio amplifier comprising:
means for modulating an audio signal to produce a first modulated signal and a second modulated signal;
means for amplifying the first modulated signal to generate a first amplified modulated signal and a second amplified modulated signal,
wherein the first amplified modulated signal is constant when the second amplified modulated signal is switching, and
wherein the second amplified modulated signal is constant when the first amplified modulated signal is switching.

17. The amplifier of claim 16 wherein modulating comprises:
means for half-wave rectifying the audio signal and an inverse of the audio signal to produce the first and second half-wave rectified signals; and
means for pulse width modulating the first and second half-wave rectified signals to produce the first and second modulated signals.

18. The amplifier of claim 16 wherein modulating comprises:
means for pulse width modulating the audio signal and an inverse of the audio signal to produce first and second pulse width modulated signals; and
means for digitally half-wave rectifying the pulse width modulated signals to produce the first and second modulated signals.

19. An electronic circuit comprising:
a modulator having at least one input for receiving an input signal, the modulator generating a first modulated signal on a first modulator output terminal and a second modulated signal on a second modulator output terminal; and
an amplifier having a first input coupled to receive the first modulated signal and a second input coupled to receive the second modulated signal, the amplifier generating a first amplified modulated signal on a first output terminal during a first time period and the amplifier generating a second amplified modulated signal on a second output terminal during a second time period,
wherein the first amplified modulated signal is constant during the first time period when the second amplified modulated signal is switching, and
wherein the second amplified modulated signal is constant during the second time period when the first amplified modulated signal is switching.

20. The circuit of claim 19 further comprising an inverter circuit for generating an inverse of the first input signal.

21. The circuit of claim 19 wherein the modulator comprises a sawtooth wave generator.

22. The circuit of claim 19 wherein the modulator comprises a plurality of comparators.

23. The circuit of claim 19 wherein the modulator comprises a digital half-wave rectifier.

24. The circuit of claim 23 wherein the digital half-wave rectifier comprises a XNOR gate, a first NOR gate and a second NOR gate.

25. The circuit of claim 19 wherein the modulator comprises a first half-wave rectifier coupled to receive the input signal and a second half-wave rectifier coupled to receive an inverse of the input signal.

26. The circuit of claim 19 wherein the amplifier comprises:
a first transistor having a first terminal coupled to a first reference voltage, a second terminal coupled to the first output terminal, and a control terminal coupled to the first amplifier input;
a second transistor having a first terminal coupled to a second reference voltage, a second terminal coupled to the first output terminal, and a control terminal coupled to the first amplifier input;
a third transistor having a first terminal coupled to the first reference voltage, a second terminal coupled to the second output terminal, and a control terminal coupled to the second amplifier input; and
a fourth transistor having a first terminal coupled to the second reference voltage, a second terminal coupled to the second output terminal, and a control terminal coupled to the second amplifier input.

27. A method of driving a speaker comprising:
generating a first pulse width modulated half-wave rectified signal on a first output terminal of a first amplifier; and
generating a second pulse width modulated half-wave rectified signal on a second output terminal of a second amplifier;
wherein the first signal is constant when the second signal is switching, and
wherein the second signal is constant when the first signal is switching.

28. The method of claim 27 further comprising modulating an audio input signal to produce a first modulated signal and a second modulated signal.

29. The method of claim 28 further comprising amplifying the first modulated signal and amplifying the second modulated signal.
